(19) United States
(12) Patent Application Publication
(10) Pub. No.: US 2001/0007084 A1
(43) Pub. Date: Jul. 5, 2001

(54) Automatic wire bonder and method for implementing thereof

(76) Inventors: Ja-Hyun Koo, Ichon-shi (KR); Bum-Wook Park, Ichon-shi (KR); Yong-Hee Lee, Ichon-shi (KR)

Correspondence Address: JACOBSON, PRICE, HOLMAN & STERN, PROFESSIONAL LIMITED LIABILITY COMPANY, 400 Seventh Street N.W., Washington, DC, 20004, US

(21) Appl. No.: 09/749,796

(22) Filed: Dec. 28, 2000

(30) Foreign Application Priority Data
Dec. 30, 1999 (KR) 1999-65803
Dec. 30, 1999 (KR) 1999-65805
Dec. 30, 1999 (KR) 1999-66324
Dec. 30, 1999 (KR) 1999-66326

(51) Int. Cl. G06F 19/00; B23K 31/02; G01R 31/26

(52) U.S. Cl. 700/117; 700/121; 228/180.5; 438/16

(57) ABSTRACT

An automatic wire bonder including a lead frame provided with N number of bonding sites, N being a positive integer; a window clamper for clamping the lead frame and for exposing M number of bonding sites, M being a positive integer; K number of cameras for obtaining images of dies and portions of the lead frame located in the exposed bonding sites, K being a positive integer; a microprocessor for calculating bonding points of the dies and the lead frame based on the obtained images; and a capillary for automatically wire bonding the chips based on the calculated bonding points. Each of the bonding sites has a die pad at a center portion thereof to attach a die and a number of leads at a peripheral portion of the bonding site. In the automatic wire bonder, the lead frame is fed into a space between the window clamp and the heater block by the M pitches at once in such a way that M numbers of bonding sites are aligned with the working areas.

### FIELD OF THE INVENTION

The present invention relates to an apparatus for assembling a semiconductor device and, more particularly, to an apparatus for automatically wire bonding a semiconductor device and a method for the implementation thereof.

### DESCRIPTION OF THE PRIOR ART

In general, an automatic wire bonder is used for electrically connecting a semiconductor chip to a lead frame. The automatic wire bonder can precisely move a bonding tool incorporated therein to a predetermined X-Y position where the lead frame is mechanically pre-positioned in a work holder. First, the automatic wire bonder recognizes a pattern of the chip and the lead frame to obtain bonding points. The bonding tool then connects the bonding points by using a gold wire.

In FIG. 1, there is shown a conventional wire bonder 100 comprising a heater block 140, a window clamp 120 provided with a window 124 for defining a working area, a bonding head 110 provided with a camera 112 and a transducer 114 having a capillary 115. In the conventional wire bonder 100, a lead frame 150 is fed into a space between the window clamp 120 and the heater block 140. The window clamp 120 clamps the lead frame 150, with the lead frame 150 being provided with a number of bonding sites 132, 134, 136. Each of the bonding sites 132, 134, 136 includes a die pad at a center portion thereof and a plurality of leads at a peripheral portion thereof. The die pad is used for attaching a die thereto. The die pad includes a number of bonding pads at its peripheral portion. The die is electrically connected to the leads of the lead frame 150 by using a gold wire.

After the window clamp 120 clamps the lead frame 150, the camera 112 carries out a pattern recognition process for the working area to obtain an image thereof. The microprocessor (not shown) calculates bonding points by using the obtained image. Thereafter, the capillary 114 starts to bond the semiconductor chip in response to a control signal from the microprocessor. The control signal is generated based on the calculated bonding points.

After one of the semiconductor chips located in the lead frame 150 is bonded, the lead frame 150 is moved a predetermined distance, e.g., a pitch of bonding sites. Again, the wire bonder 100 repeats the above processes to bond another semiconductor chip.

One of the major shortcomings of the above-described wire bonder 100 is that it cannot implement a pattern recognition process for a next semiconductor chip to be bonded while the capillary 115 is carrying out a wire bonding.

### SUMMARY OF THE INVENTION

It is, therefore, an object of the present invention to provide an apparatus for wire bonding semiconductor chips, which is capable of reducing an overall bonding time.

It is another object of the present invention to provide a method for bonding semiconductor chips, which is capable of carrying out a pattern recognition process for a next semiconductor chip to be bonded while a capillary is bonding a semiconductor chip.

In accordance with one aspect of the present invention, there is provided an apparatus for assembling a semiconductor device, comprising a lead frame provided with N number of bonding sites, each of which sites has a die pad at a center portion thereof to attach a die and a number of leads at a peripheral portion of the bonding site, the die having a number of bonding pads, with N being a positive integer; a window clamper for clamping the lead frame and for exposing M number of bonding sites, with M being a positive integer; K number of cameras for obtaining images of dies and portions of the lead frame located in the exposed bonding sites, with K being a positive integer; a microprocessor for calculating bonding points of the dies and the lead frame based on the obtained images; and a capillary for automatically wire bonding the chip based on the calculated bonding points.

In accordance with another aspect of the present invention, there is provided a method for automatically wire-bonding a semiconductor device, the method comprising the steps of a) assigning identification (ID) numbers to all chips attached to a lead frame; b) clamping N number of working chips, selected from the total number of chips, to N number of working areas, each of the working chips being located at a corresponding working area, wherein N is a positive number; c) obtaining all images of working areas by using M number of cameras and calculating N sets of bonding points based on the images, wherein M is a positive integer; d) moving a capillary to one of the working areas to electrically connect a working chip to leads located therein; e) waiting a predetermined time until the bonding of the working chip is finished; f) moving the capillary to another working area to electrically connect a working chip to leads located therein based on a corresponding set of bonding points; g) repeating the steps d) to f) until all of the working chips are bonded; and h) repeating the steps b) to g) until all of the chips are bonded.

### BRIEF DESCRIPTION OF THE DRAWINGS

The above and other objects and features of the present invention will become apparent from the following description of the preferred embodiments given in conjunction with the accompanying drawings, in which:

FIG. 1 is a perspective view setting forth a portion of a conventional wire bonder;

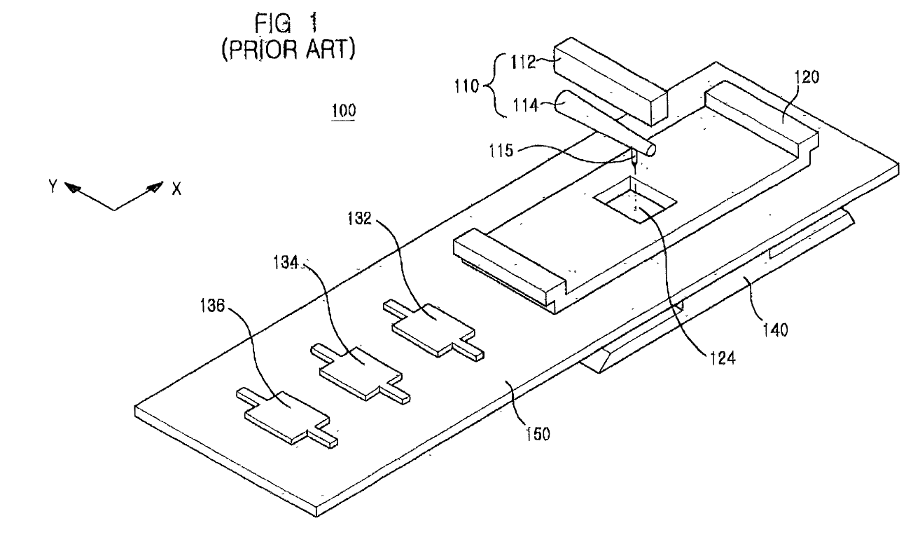

FIG. 2 is a perspective view illustrating a portion of a wire bonder in accordance with a first preferred embodiment of the present invention;

FIG. 3 is a flow chart showing a method for implementing the first preferred embodiment of the present invention;

FIG. 4 is a perspective view illustrating a portion of a wire bonder in accordance with a second preferred embodiment of the present invention;

FIG. 5 is a flow chart setting forth a method for implementing the second preferred embodiment of the present invention;

FIG. 6 is a perspective view representing a portion of a wire bonder in accordance with a third preferred embodiment of the present invention;

FIG. 7 is a flow chart showing a method for implementing the third preferred embodiment of the present invention;

FIG. 8 is a perspective view depicting a portion of a wire bonder in accordance with a fourth preferred embodiment of the present invention; and

FIG. 9 is a flow chart illustrating a method for implementing the fourth preferred embodiment of the present invention.

### DETAILED DESCRIPTION OF THE PREFERRED EMBODIMENTS

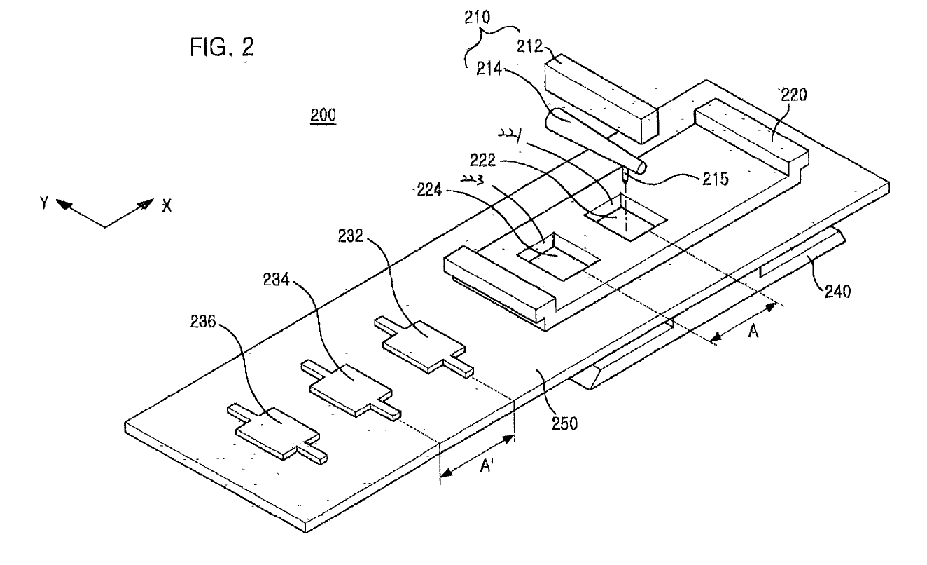

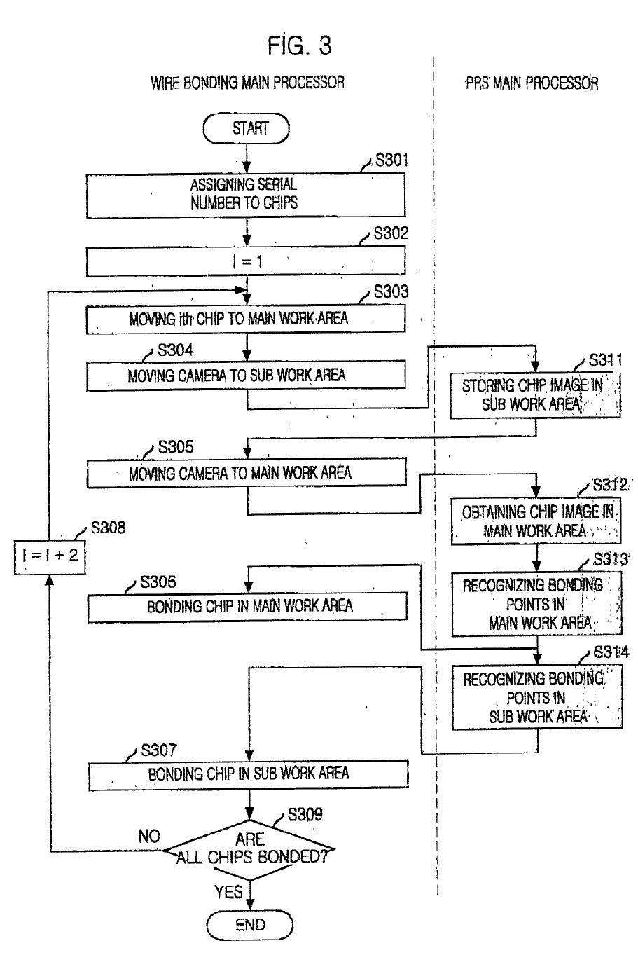

There are provided in FIGS. 2, 4, 6 and 8 perspective views of automatic wire bonders and in FIGS. 3, 5, 7, and 9 flow charts setting forth methods for implementing the respective automatic wire bonders in accordance with preferred embodiments of the present invention. It should be noted that like parts appearing in FIGS. 2 to 9 are represented by like reference numerals.

In FIG. 2, there is provided a perspective view of a first preferred embodiment of the inventive automatic wire bonder 200 comprising a heater block 240, a window clamp 220 provided with a pair of windows 221, 223 for defining two working areas 222, 224 and a bonding head 210 provided with a camera 212 and a transducer 214 with a capillary 215.

In the automatic wire bonder 200, if a lead frame 250 is fed into a space between the window clamp 220 and the heater block 240, the window clamp 220 clamps the lead frame 250. The lead frame 250 is provided with a number of bonding sites. The windows 221, 223 are designed in such a way that a pitch A of the windows is equal to the pitch A′ of the bonding sites 232, 234, 236. In the first preferred embodiment, the lead frame 250 is fed into the space such that both window pitches are aligned with bonding sites at once. Each of the bonding sites 232, 234, 236 includes a die pad at a center portion thereof and a plurality of leads at a peripheral portion thereof. The die pad is used for bonding a die thereto. The die includes a number of bonding pads at its peripheral portion. The die is electrically connected to the leads of the lead frame 250 by using a gold wire. The transducer 214 provides ultra sonic power to the capillary 215 while the capillary 215 presses the gold wire at a bonding point.

FIG. 3 is a flow chart illustrating the operation of the automatic wire bonder 200 in accordance with the first preferred embodiment of the present invention. A microprocessor (not shown) of the automatic wire bonder 200 includes a wire bonding main processor and a pattern recognition system (PRS) main processor. In the automatic wire bonder 200, the lead frame 250 is fed into the space between the window clamp 220 and the heater block 240 by the two pitches at once in such a way that two bonding sites 232, 234 are aligned with the working areas 222, 224, respectively.

At step S301, the wire bonding main processor assigns serial numbers (e.g., 1, 2, 3, . . . N) to all of the chips in sequence upon entering the window clamp 220. Next, at step S302, I is set to 1.

At step S303, an Ith chip is moved to a main working area 222. Next, at step S304, a camera 212 of bond head 210 is moved to a sub working area 224. Meanwhile, in the PRS main processor, the camera obtains a chip image of the sub working area 224 and stores the obtained chip image in the PRS main processor, at step S311.

At step S305, the camera 212 is moved to the main working area 222 to obtain a chip image of the main working area 222 in response to a first control signal from the PRS main processor. The chip image of the main working area 222 is stored into the PRS main processor, at step S312.

At step S313, the PRS main processor calculates bonding points of the main working area 222 based on the chip image of the main working area 222. The wire bonding main processor controls the bonding head 210 based on the calculated bonding points in such a way that bonding points of the main working area 222 are electrically bonded to leads of the lead frame 250 with a gold wire using a capillary 215 of the bonding head 210.

During the bonding of the main working area 222, the PRS main processor calculates bonding points of the sub working area 224 based on the stored chip image of the sub working area 224, at step S314. After the bonding of the main working area 222, the wire bonding main processor controls the bonding head 210 in such a way that bonding points of the sub working area 224 are electrically bonded to leads of the lead frame 250, at step S307.

The process then moves to step S309 where it is determined whether or not all of the chips in the lead frame 250 have been bonded. If not, the wire bonding main processor adds 2 to I at step S308 and returns to the step S303. When all of the chips in the lead frame 250 have been bonded, the wire bonding main processor ends all of the processes.

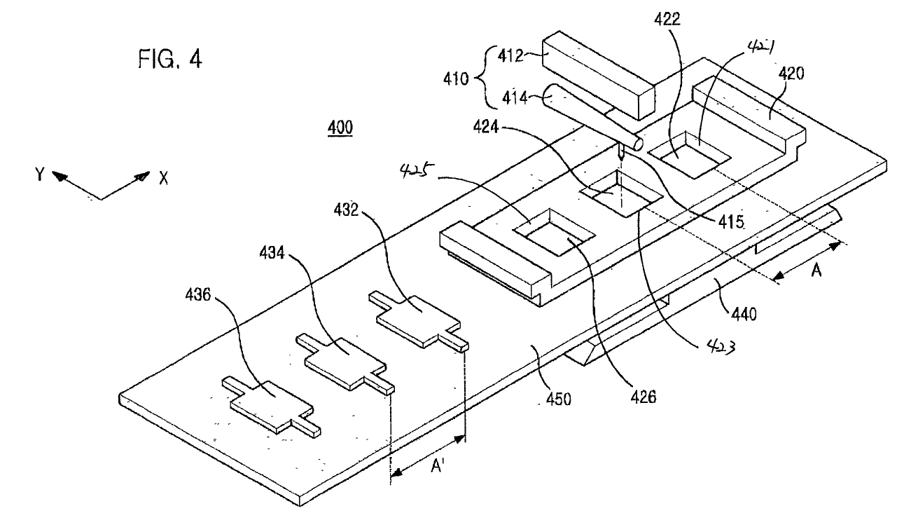

In FIG. 4, there is provided a perspective view of a second preferred embodiment of the inventive automatic wire bonder. The automatic wire bonder 400 of the second preferred embodiment of the present invention is similar to that of the first preferred embodiment shown in FIG. 2 except that a window clamp 420 is provided with three windows 421, 423, 425 for defining three working areas 422, 424, 426, wherein a pitch A of the windows 421, 423, 425 is equal to a pitch A′ of bonding sites 432, 434, 436. In the second preferred embodiment, the lead frame 450 is fed into a space between the window clamp 420 and the heater block 440 in such a way that the three bonding sites 432, 434, 446 are each aligned with a respective working area 422, 424, 426.

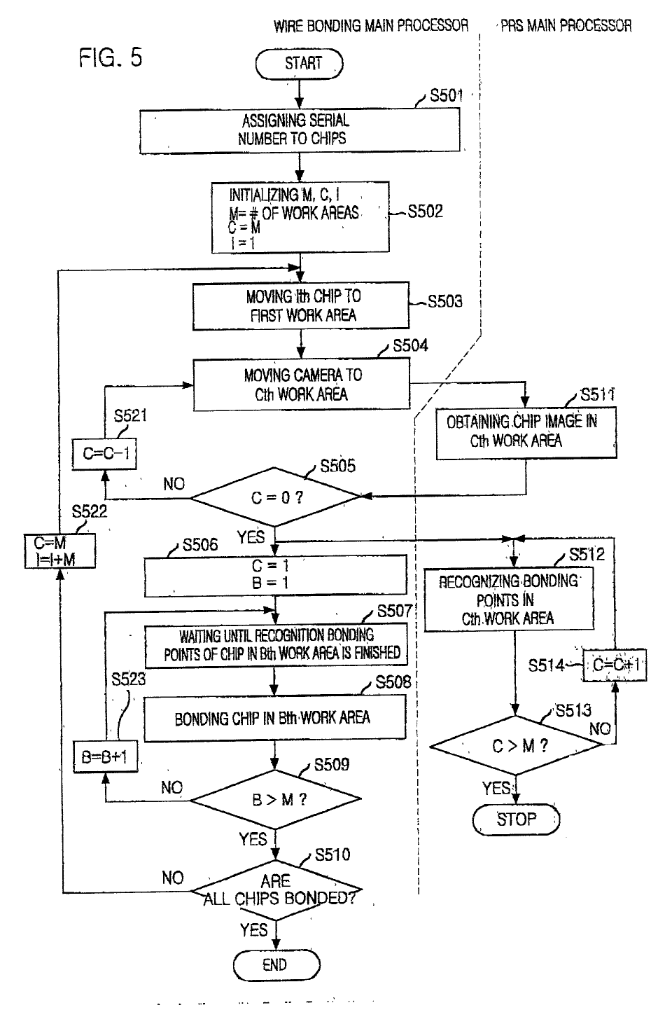

The operation of the automatic wire bonder 400 will be described in more detail with reference to FIG. 5. A microprocessor (not shown) of the automatic wire bonder 400 includes a wire bonding main processor and a pattern recognition system (PRS) main processor. In the automatic wire bonder 400, the lead frame 450 is fed into the space between the window clamp 420 and the heater block 440 in such a way that each of the three bonding sites 432, 434, 436 is aligned with a respective working area 422, 424, 426 at the same time.

Upon start up, at step S501, the wire bonding main processor assigns serial numbers (e.g., 1, 2, 3, . . . N) to all of the chips in sequence of entering the window clamp 420. Next, at step S502, M, C and I are initialized. Specifically, M is the number of working areas, C is equal to M and I is equal to 1.

At step S503, an Ith chip is moved to a first working area 422. Next, at step S504, a camera 412 of bonding head 410 is moved to a Cth sub working area, e.g., 424. Meanwhile, in the PRS main processor, the camera 412 obtains a chip image of the sub working area 424 and stores the obtained chip image in the PRS main processor, at step S511. The process goes to step S505 where it is determined whether or not C is equal to 0. If C is not equal to 0, the wire bonding main processor subtracts 1 from C at step S521 and the process returns to the step S504 to repeat the steps S504 and S511. If C is equal to 0, the process goes to step S506 to set C and B to 1.

At step S512, the PRS main processor calculates bonding points of the Cth working area based on the stored Cth chip image. The process goes to step S513 where it is determined whether or not C is larger than M. If C is not larger than M, the PRS main processor adds 1 to C at step S514 and the process returns to the step S512 to repeat the steps S512 and S513. If C is larger than M, the processor stops these processes.

After the step S506, the process goes to step S507 where the bonding head 410 waits for the recognition of bonding points in the Bth working area. Then, the bonding head 410 bonds the chip in the Bth working area, at step S508. The process goes to step S509 where it is determined whether or not B is larger than M. If B is not larger than M, the wire bonding main processor adds 1 to B at step S523 and the process returns to the step S507 to repeat the steps S507, S508 and S509. If B is larger than M, the process goes to step S510 where it is determined whether or not all of the chips in the lead frame 450 have been bonded. If all of the chips have not been bonded, the wire bonding main processor sets C to M and I to I+M at step S522 and returns to the step S503. If all the chips have been bonded, the wire bonding main processor stops all these processes.

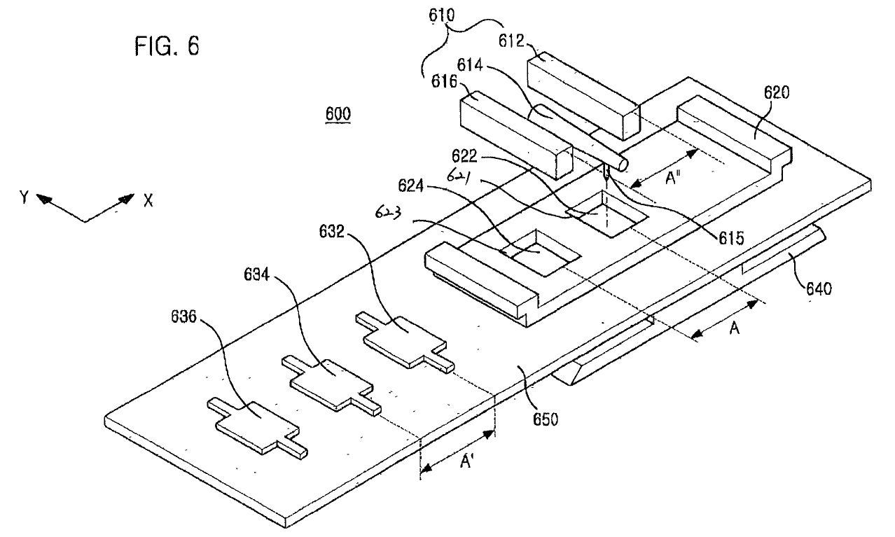

In FIG. 6, there is provided a perspective view of a third preferred embodiment of the inventive automatic wire bonder. The automatic wire bonder 600 of the third preferred embodiment of the present invention is similar to that of the first preferred embodiment shown in FIG. 2 except that the bonding head 610 is provided with two cameras 612, 616, wherein a pitch A of the windows 621, 623 is equal to a pitch A′ of the bonding sites 632, 634, 636. In the third preferred embodiment, in order to reduce the pattern recognition time, two cameras 612, 616 are installed into the bonding head 610. It should be noted that a pitch A″ of cameras 612, 616 is equal to the pitch A of the windows 621, 623. The lead frame 650 is fed into a space between the window clamp 620 and the heater block 640 in such a way that each of two bonding sites 632, 634 is aligned with a respective working area 622, 624 at the same time.

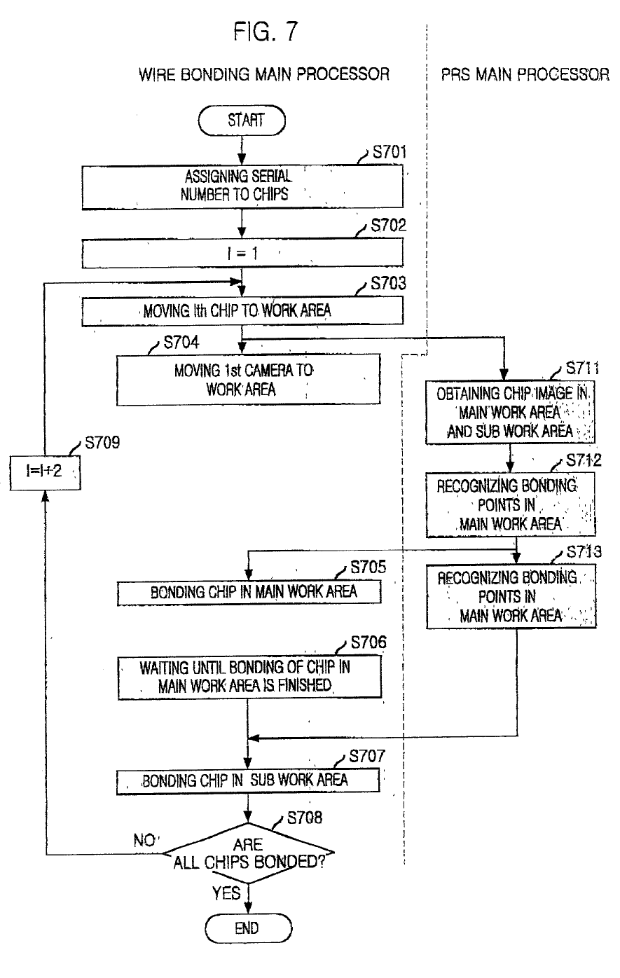

FIG. 7 is a flow chart illustrating the operation of the automatic wire bonder 600 in accordance with the third preferred embodiment of the present invention. A microprocessor (not shown) of the automatic wire bonder 600 includes a wire bonding main processor and a pattern recognition system (PRS) main processor. In the automatic wire bonder 600, the lead frame 650 is fed into a space between the window clamp 620 and the heater block 640 in such a way that two bonding sites 632, 634 are aligned with the working areas 622, 624 at the same time.

At step S701, the wire bonding main processor assigns serial numbers (e.g., 1, 2, 3, . . . N) to all of the chips in sequence of entering the window clamp 620. Next, at step S702, I is set to 1.

At step S703, an Ith chip is moved to a main working area 622. Next, at step S704, a first camera 612 of bond head 610 is moved to a sub working area 624. Meanwhile, in the PRS main processor, the first camera 612 obtains a chip image of the main working area 622 and the second camera 616 obtains a chip image of the sub working area 624 to store the obtained chip images in the PRS main processor, at step S711.

At step S712, the PRS main processor recognizes bonding points of the obtained chip image in the main working area 622. The process goes to step S705 to bond the chip in the main working area 622 by using the capillary 614.

During the bonding of the main working area 622, at step S713, the PRS main processor calculates bonding points of the obtained chip image in the sub working area 624. At step S706, the wire bonding main processor waits until the chip in the main working area 622 is bonded. After the bonding of the chip in the main working area 622, the process goes to the step S707 for bonding a chip in the sub working area 624 based on the bonding points calculated at the step S713.

The process then moves to step S708 where it is determined whether or not all of the chips in the lead frame 650 have been bonded. If all the chips have not been bonded, the wire bonding main processor adds 2 to I at step S709 and returns to the step S703. If all the chips have been bonded, the wire bonding main processor ends all of the processes.

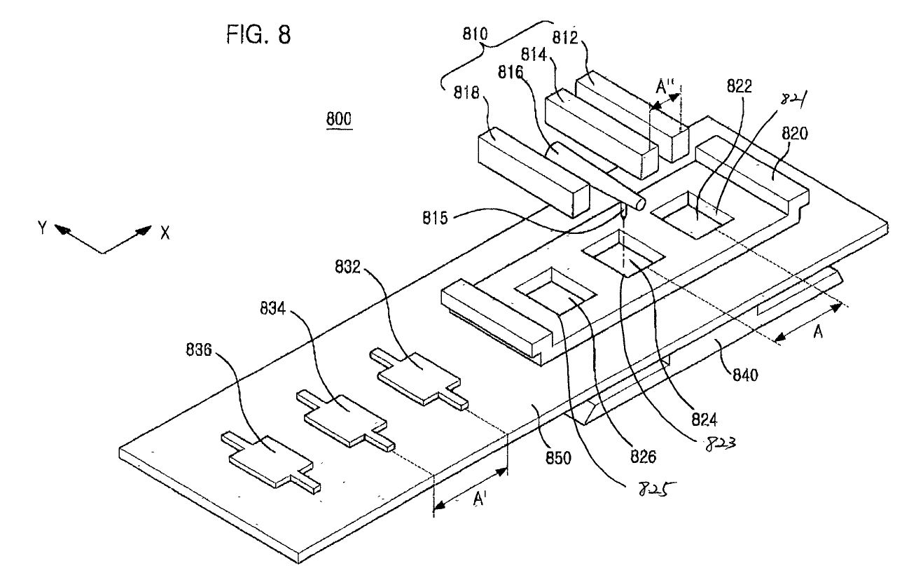

In FIG. 8, there is provided a perspective view of a fourth preferred embodiment of the inventive automatic wire bonder. The automatic wire bonder 800 of the fourth preferred embodiment of the present invention is similar to that of the second preferred embodiment shown in FIG. 4 except that a bonding head 810 is provided with three cameras 812, 814, 818, wherein a pitch A of windows 821, 823, 825 is equal to a pitch A′ of bonding sites 832, 834, 836. In the third preferred embodiment, by utilizing three cameras 812, 814, 818, the automatic wire bonder 800 can drastically reduce the bonding time of chips in comparison with the prior art wire bonder 100. It should be noted that a pitch A″ of cameras 812, 814 is equal to the pitch A of windows 821, 823. The lead frame 850 is fed into a space between the window clamp 820 and the heater block 840 in such a way that each of the three bonding sites 832, 834, 836 is aligned with a respective working area 822, 824, 826 at the same time.

It should also be understood that the present invention is not limited to the number of cameras and the number of windows of the window clamp, provided that the automatic wire bonder is made to implement PRS in parallel.

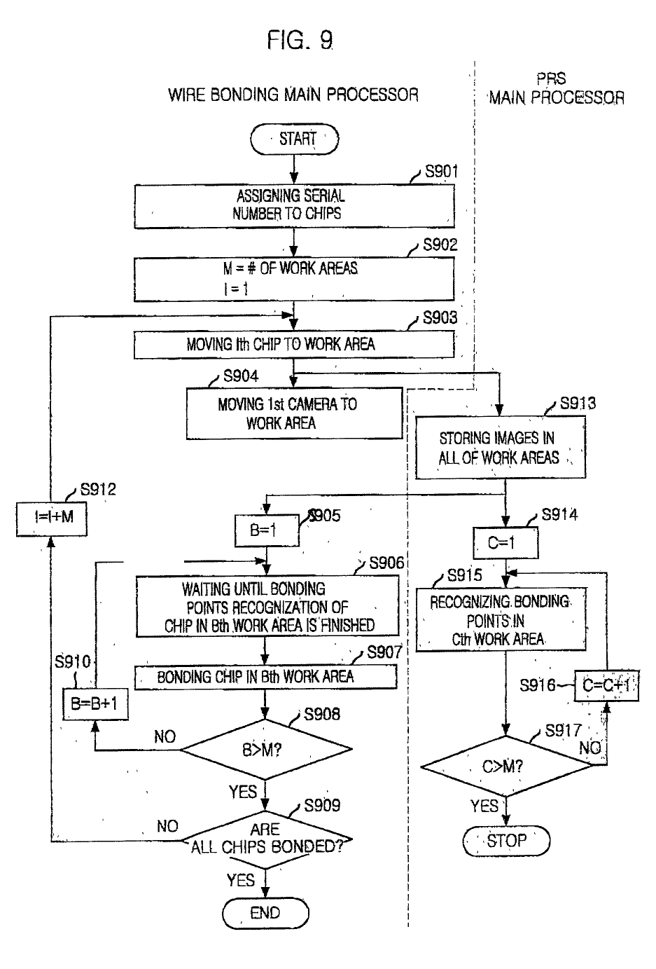

The operation of an automatic wire bonder 800 will be described in more detail with reference to FIG. 9. A microprocessor (not shown) of the automatic wire bonder 800 includes a wire bonding main processor and a pattern recognition system (PRS) main processor. In the automatic wire bonder 800, the lead frame 850 is fed into a space between the window clamp 820 and the heater block 840 in such a way that the three bonding sites 832, 834, 836 are aligned with the working areas 822, 824, 826 at the same time.

Upon start up, as step S901, the wire bonding main processor assigns serial numbers (e.g., 1, 2, 3, . . . N) to all of the chips in sequence of entering the window clamp 820. Next, at step S902, M and I are initialized. Specifically, M is the number of working areas and I is equal to 1.

At step S903, an Ith chip is moved to a first working area 822. Meanwhile, in the PRS main processor, each of the cameras 812, 814, 818 of bonding head 810 are moved to a corresponding working area, respectively. Each of the cameras 812, 814, 818 obtains a corresponding chip image of the sub working areas 822, 824, 826 and stores the obtained chip images in the PRS main processor, at step S913. The process goes to steps S905 and S914 to set each of B and C equal to 1.

After the step S914, the process goes to step S915 to recognize bonding points based on the Cth stored chip image. The process then goes to step S917 where it is determined whether or not C is larger than M. If C is not larger than M, the wire bonding main processor adds 1 to C at step S916 and the process returns to the step S915 to repeat the steps S915 and S917. If C is larger than M, the process stops.

On the other hand, after the step S905, the wire bonding main processor waits until the recognition of the chip in the Bth working area is finished, at step S906. When the recognition of bonding points in the Bth working area is ended, the process goes to step S907 to bond the chip in the Bth working area. Then, the process goes to step S908 where it is determined whether or not B is larger than M. If B is not larger than M, the wire bonding main processor adds 1 to B at step S910 and the process returns to the step S906. If B is larger than M, the process goes to step S909 to determine whether or not all of the chips have been bonded. If all of the chips have not been bonded, the wire bonding main processor adds M to I at step S912 and the process returns to the step S903. If all of the chips have been bonded, the wire bonding main processor stops all of the processes.

In comparison with the prior art, the present invention can drastically reduce the bonding time of chips by utilizing a number of cameras. This is achieved by designing a window clamp in such a way that the lead frame can be fed into a space between the window clamp and the heater block by the M pitches at once.

While the present invention has been described with respect to the particular embodiments, it will be apparent to those skilled in the art that various changes and modifications may be made without departing from the scope of the invention as defined in the following claims.

What is claimed is:

1. An apparatus for assembling a semiconductor device, comprising:
a lead frame provided with N number of bonding sites, each of which has a die pad at a center portion thereof to attach a die and a number of leads at a peripheral portion of the bonding site, the die having a number of bonding pads, with N being a positive integer;
a window clamper for clamping the lead frame and for exposing M number of bonding sites, with M being a positive integer;
K number of cameras for obtaining images of dies and portions of the lead frame located in the exposed bonding sites, with K being a positive integer;
a microprocessor for calculating bonding points of the dies and the lead frame based on the obtained images; and
a capillary for automatically wire bonding chips based on the calculated bonding points.

2. The apparatus of claim 1, wherein K and M are equal to 1 and 2, respectively.

3. The apparatus of claim 1, wherein K and M are equal to 1 and 3, respectively.

4. The apparatus of claim 1, wherein K is equal to M.

5. The apparatus of claim 1, wherein K is equal to 2.

6. The apparatus of claim 1, wherein K is equal to 3.

7. The apparatus of claim 1, wherein the capillary bonds one of the exposed bonding sites and the cameras recognize images of other exposed bonding sites.

8. A method for automatically wire-bonding a semiconductor device, the method comprising the steps of:
a) assigning identification (ID) numbers to all chips attached to a lead frame;
b) clamping N number of working chips, selected from the chips, to N number of working areas, each of the working chips being located at a corresponding working area, wherein N is a positive number;
c) obtaining all images of working areas by using M number of cameras and calculating N sets of bonding points based on the images, wherein M is a positive integer;
d) moving a capillary to one of the working areas to electrically connect a working chip to leads located therein;
e) waiting a predetermined time until the bonding of the working chip is finished;
f) moving the capillary to another working area to electrically connect a working chip to leads located therein based on a corresponding set of bonding points;
g) repeating the steps d) to f) until all of the working chips are bonded; and
h) repeating the steps b) to g) until all of the chips are bonded.

9. The method of claim 8, wherein N is equal to M.

10. The method of claim 9, wherein N is 2.

11. The method of claim 9, wherein N is 3.

12. The method of claim 8, wherein M is 1 and N is 2.

13. The method of claim 8, wherein M is 1 and N is 3.
